(19) United States
(12) Patent Application Publication
(10) Pub. No.: US 2023/0178571 A1
(43) Pub. Date: Jun. 8, 2023

(54) PIXEL ARRANGEMENT, PIXEL MATRIX, IMAGE SENSOR AND METHOD OF OPERATING A PIXEL ARRANGEMENT

(71) Applicant: ams Sensors USA Inc., Plano, TX (US)

(72) Inventors: Kevin TETZ, Boise, ID (US); Scott JOHNSON, Boise, ID (US)

(21) Appl. No.: 17/543,302

(22) Filed: Dec. 6, 2021

(51) Int. Cl. H01L 27/146

(52) U.S. Cl. CPC H01L 27/14614; H01L 27/14649; H01L 27/1462

(57) ABSTRACT

A pixel arrangement (10) is provided. The pixel arrangement (10) comprises a photosensitive stage (20) being configured to generate electrical signals by converting electromagnetic radiation, wherein the photosensitive stage (20) forms at least one sub-pixel of a first type (40) comprising a photodiode (41) that is configured generate a low sensitivity signal, and at least one sub-pixel of a second type (50) comprising a photodiode (51) that is configured to generate a high sensitivity signal. The pixel arrangement (10) further comprises a sample-and-hold stage (30), wherein the sample-and-hold (30) stage is electrically coupled to the photosensitive stage (20) via a diffusion node (60) and configured to sample and store the electrical signals from the photosensitive stage (20).

### FIELD OF INVENTION

The present invention relates to a pixel arrangement, a pixel matrix, an image sensor and a method for operating a pixel arrangement.

### BACKGROUND OF THE INVENTION

CMOS image sensors are used in a wide range of applications, some of which require a high dynamic range (HDR). The dynamic range (DR) is limited on the one side by the noise floor at low light conditions, and by saturation effects at high light conditions on the other side.

Most of the available DR techniques are designed for rolling shutter pixels, but not being global shutter friendly. In global shutter mode all the pixels of a pixel matrix are exposed during the same time period. At the end of integration time, the charge transfer operations for all rows of the pixel matrix happen simultaneously. The signals are stored in a pixel level memory and subsequently read out.

An object to be achieved is to provide a pixel arrangement with a high dynamic range and a method for operating such pixel arrangement. A further object is to provide an image sensor comprising the pixel arrangement or a pixel matrix according to the pixel arrangement.

These objects are achieved with the subject-matter of the independent claims. Further developments and embodiments are described in dependent claims.

### SUMMARY OF THE INVENTION

Here and in the following, the terms “pixel arrangement” and “pixel”, refer to a light receiving element, which might be arranged in a two-dimensional array, also called matrix, with other pixels. Pixels in the array are arranged in rows and columns. The terms “row” and “column” can be used interchangeably, since they depend only on the orientation of the pixel array. The pixel might also include circuitry for controlling signals to and from the pixel. Thus, the pixel may form a so-called active pixel. The pixel may receive light in an arbitrary wavelength range. The term “light” may refer to electromagnetic radiation in general, including infrared (IR) radiation, ultraviolet (UV) radiation and visible (VIS) light, for example.

In an embodiment, a pixel arrangement comprises a photosensitive stage. The photosensitive stage is configured to generate electrical signals by converting electromagnetic radiation. The photosensitive stage forms at least one sub-pixel of a first type comprising a photodiode that is configured to generate a low sensitivity signal. This can mean that the photodiode of the pixel of the first type is implemented as low sensitivity photodiode. In other words, the photodiode of the pixel of the first type may be configured with low sensitivity to generate a signal under high incident irradiance. That signal is referred hereafter as the low sensitivity signal.

The photosensitive stage further forms at least one sub-pixel of a second type comprising a photodiode that is configured to generate a high sensitivity signal. This can mean that the photodiode of the pixel of the second type is implemented as high sensitivity photodiode. In other words, the photodiode of the pixel of the second type may be configured with high sensitivity to generate a signal under low incident irradiance. That signal is referred hereafter as the high sensitivity signal.

The pixel arrangement further comprises a sample-and-hold stage, also referred to herein as an S/H stage or S/H circuit. The S/H stage is electrically coupled to the photosensitive stage via a diffusion node. The S/H stage is configured to sample and store the electrical signals from the photosensitive stage.

The pixel arrangement may in particular form a global shutter pixel. The pixel arrangement may form one pixel within a matrix of pixels. The pixel is subdivided into two or more sub-pixels, wherein each sub-pixel comprises a respective photodiode.

Here and in the following, the sub-pixel of the first type may be referred to as first sub-pixel and the photodiode comprised by that sub-pixel may be referred to as first photodiode. Similarly, the sub-pixel of the second type may be referred to as second sub-pixel and the photodiode comprised by that sub-pixel may be referred to as second photodiode. When in the following a plurality of first or second sub-pixels/photodiodes is referred to, a plurality of sub-pixels/photodiodes of the respective type is meant.

The pixel arrangement may comprise more than one first sub-pixel for generating a low sensitivity signal. Further, the pixel arrangement may comprise more than one second sub-pixel for generating a high sensitivity signal. For example, the pixel arrangement comprises one first and three second sub-pixels that are arranged in a 2×2 array. The pixel arrangement may comprise a plurality of first sub-pixels and corresponding first photodiodes. The pixel arrangement may further comprise a plurality of second sub-pixels and corresponding second photodiodes. All information and features given here and in the following for one first or second sub-pixel, respectively, can apply accordingly to all further first or second sub-pixels.

The pixel arrangement may be arranged in a substrate, in particular a semiconductor substrate. The first photodiode and the second photodiode may in particular be pinned photodiodes. The first photodiode and the second photodiode may be of a same design. This means that the first photodiode and the second photodiode may be equal. The first photodiode may be provided with a filter layer in order to attenuate the electromagnetic radiation. It is also possible that an integration time of the first photodiode is shorter than an integration time of the second photodiode. In addition or alternatively, the first photodiode and the second photodiode may be different. For example, the second photodiode may have a larger photoactive area than the first photodiode in order to generate more charge carriers than the first photodiode. The first photodiode and the second photodiode convert electromagnetic radiation into respective charge signals. The first photodiode and second photodiodes share a common diffusion node. The diffusion node may be implemented as floating diffusion node. The diffusion node may be called FD node. The diffusion node comprises a capacitance. The capacitance forms a storage element of the pixel. The diffusion node may be formed by a doped well in the semiconductor substrate.

The low sensitivity signal from the first sub-pixel may be provided for high light conditions, i.e. high illuminance. In this case, the charge signal generated by the photodiode is already large and does not need to be “artificially” increased, for example by a high gain, long exposure times etc. In contrast, the electromagnetic radiation may be attenuated before being converted by the first photodiode into a charge signal. If such charge signal was increased, for example by a high conversion gain (HCG), saturation effects could occur. Saturation could occur, for example, because the potential well of the photodiode and/or of a storage element within the pixel is not sufficiently large to carry all photo-induced charge carriers. The high sensitivity signal from the second sub-pixel may be provided for low light conditions, i.e. low illuminance. In that case, the charge signal generated by the photodiode is small and should be increased, for example by a high gain, long exposure times and/or an enlarged photo-active area in order to obtain a good signal-to-noise ratio (SNR). The low sensitivity signal and the high sensitivity signal may be referred to as video signals.

The S/H stage may comprise circuit components that are integrated in or on the semiconductor substrate. For example, the S/H stage comprises capacitors for storing the respective signals from the photosensitive stage. Thus, the S/H stage comprise pixel-internal memory elements. For example, the capacitors may be implemented as metal-oxide-semiconductor (MOS) capacitors. Alternatively, the capacitors may be formed as metal-insulator-metal (MIM) capacitors. Further, the capacitors may be implemented as metal fringe capacitors or as so-called poly-N capacitors. Further, the S/H stage may comprise switches to electrically connect the diffusion node to one or more capacitors of the S/H stage. As such, the electrical signals generated by the photosensitive stage can be stored on the capacitors. The S/H stage stores the electrical signals from the photosensitive stage in a voltage domain. This can mean that the S/H stage stores altered versions of the low sensitivity signal and the high sensitivity signal. In particular, charge signals generated by the photodiodes may be amplified and transformed into respective voltage signals before being stored on capacitors of the S/H stage. For example, an amplifying stage may be configured to generate, based on the respective charge signal, an amplified signal. The amplified signal may be a voltage signal that is based on the low sensitivity signal or the high sensitivity signal, respectively. The amplifying stage may form a common-drain amplifier, also known as source follower. Thus, the S/H stage stores amplified versions of the low sensitivity signal and the high sensitivity signal. However, since the stored signals are based on the photo-induced charge signals, they may also be referred to as low sensitivity signal and high sensitivity signal, respectively. Apart from the photo-induced electrical signals the S/H stage may further store reset levels of the pixel arrangement. The stored video signals and reset levels may be referred to as pixel output signals. It may be desired to store the pixel output signals in the voltage domain rather than in the charge domain for dark current reasons and to reduce the parasitic light sensitivity (PLS) of the pixel.

In an embodiment, the pixel arrangement is electrically connected to a column bus via one or more select gates. The select gate(s) may be comprised by the pixel arrangement. The select gate(s) may form a readout stage of the pixel arrangement. The column bus may or may not be comprised by the pixel arrangement. Alternatively, only a portion of the column bus is comprised by the pixel arrangement. The select gate is part of a select transistor. By applying a select signal to the select gate the select transistor becomes conductive, such that a pixel output signal is forwarded via the column bus to a readout circuit. For example, the readout circuit comprises an analog-to-digital converter (ADC). Thus, the pixel arrangement may be provided with a global shutter voltage domain readout.

By means of the high sensitivity signal and the low sensitivity signal the pixel arrangement enables HDR operation, for example from about 60 dB up to 90 dB, or up to 100 dB or more than 100 dB. The HDR allows for better highlight and shadow capturing encountered in real world scenes, while maintaining the advantages of a global shutter (GS) implementation, such as low motion artifacts and reduced illumination times.

In a further embodiment, the first photodiode and the second photodiode are configured to detect electromagnetic radiation in a substantially same wavelength range. This can mean that the first photodiode and the second photodiode are configured to detect electromagnetic radiation in at least an overlapping wavelength range. In a preferred embodiment, both the first photodiode and the second photodiode are configured to detect electromagnetic radiation in the infrared (IR), especially the near infrared (NIR) or the short-wave infrared (SWIR) wavelength range. Due to the monochromatic implementation of the photodiodes a high dynamic range in a target wavelength range can be covered. The infrared sensitivity can be used in dark environments where video feed is required. The photodiodes can be synchronized with illumination from an active NIR/SWIR illumination source such as a VCSEL or LED.

In a further embodiment, the photosensitive stage and the sample-and-hold stage are arranged on or at a main surface of a semiconductor substrate. This means that the semiconductor substrate may be comprised by the pixel arrangement at least partially. The semiconductor substrate comprises a semiconductor material, for example silicon. The semiconductor substrate has a main plane of extension which runs in lateral directions. The semiconductor substrate comprises a back surface that is, in a transversal direction, opposite to the main surface. The photosensitive stage and the sample-and-hold stage may be integrated in the semiconductor substrate and fabricated by standard CMOS processing. On the main surface of the semiconductor substrate a dielectric layer may be arranged. Metal layers may be embedded in the dielectric layer and may serve as capacitor plates for the S/H stage. In addition, the metal layers may form a wiring to electrically connect the pixel arrangement to other circuit components in the semiconductor substrate, for example the readout circuit.

According to a further embodiment, the photosensitive stage is illuminated by electromagnetic radiation from the back surface of the semiconductor substrate. In this scenario, portions of semiconductor substrate might be removed. In particular, the substrate might be ground or polished. The polished/ground surface forms the back surface of the substrate. This means that the back surface of the substrate forms a radiation entrance side.

Thus, in that embodiment, the pixel arrangement is backside illuminated (BSI). Because it is BSI, it is possible to incorporate advanced processing techniques to dramatically improve sensitivity in the near-infrared (NIR) portion of the electromagnetic spectrum. For example, the electromagnetic radiation is not blocked by metal layers used as wiring. However, the pixel arrangement can also be front side illuminated (FSI). In that case the photosensitive stage is illuminated by electromagnetic radiation via the main surface of the semiconductor substrate.

According to an embodiment, the pixel arrangement comprises a filter layer. The filter layer is arranged between the incident electromagnetic radiation and the first sub-pixel. The filter layer is configured to reduce an intensity of the electromagnetic radiation. This can mean that the filter layer is arranged on or at the back surface of the semiconductor substrate, such that the electromagnetic radiation has to pass the filter layer before reaching the first sub-pixel with the first photodiode. The filter layer is aligned with the first sub-pixel. This can mean that the filter layer is structured such that it only covers those portions of the substrate that correspond to the first sub-pixel. The filter layer may comprise a semitransparent material. This can mean that the filter layer forms a partially opaque or absorbing film. For example, the filter layer comprises a photoresist, which may be treated to reduce its transparency. Alternatively, the filter layer may comprise polytetrafluoroethylene (PTFE), which may include additives to adjust its transparency. In another example, the filter layer comprises titanium nitride (TiN) or zirconium nitride (ZrN). That the filter layer comprises titanium-silicocarbide (TiSiC), titanium-silicium-nitride (TiSiN) or titanium-aluminum-nitride (TiAlN) is also possible. The filter layer may also comprise a combination of some of the above materials. For example, the transmittance of the filter layer is in the range of 1 to 20%. Thus, the filter layer is provided for optical attenuation. The signal-to-noise ratio (SNR) at the transition from low light conditions to high light conditions as well as the dynamic range are explicitly set by the degree of attenuation set by the partially transmissive film, i.e. the filter layer. Thus, the dynamic range of the pixel arrangement can be increased by providing the first sub-pixel with the filter layer. This means that the pixel arrangement makes use of the filter layer to change the sensitivity of the first sub-pixel to provide significant increase to the dynamic range of a sensor device implementing the pixel arrangement. In particular, the sensitivity of the first sub-pixel is reduced by the filter layer, which results in an increase of the effective dynamic range.

According to an embodiment, an integration time of the first photodiode is shorter than an integration time of the second photodiode. The respective charge signals generated by the photodiodes at a given illuminance can be varied by different integration times. For example, a long integration time can be used for generating an increased charge signal, i.e. the high sensitivity signal, while a short integration time can be used for generating a reduced charge signal, i.e. the low sensitivity signal, and thus preventing saturation. By using two or at least two integration times the dynamic range of the pixel arrangement can be increased.

According to an embodiment, the pixel arrangement further comprises a first transfer gate configured to transfer the low sensitivity signal of the first sub-pixel to the diffusion node. The first transfer gate is arranged between the first photodiode and the diffusion node. According to an embodiment, the pixel arrangement further comprises a second transfer gate configured to transfer the high sensitivity signal of the second sub-pixel to the diffusion node. In case further second sub-pixels are comprised by the pixel arrangement, the further second sub-pixels may be provided with further second transfer gates with corresponding features as described in the following. The second transfer gate is arranged between the second photodiode and the diffusion node. The transfer gates may be implemented as transfer switches. For example, the transfer gates may be part of a respective transfer transistor comprising a first terminal connected to the respective photodiode and a second terminal connected to the diffusion node. By applying a transfer signal to the transfer gate the transfer transistor becomes conductive, such that charge carriers diffuse from the photodiode towards the diffusion node. By triggering the transfer towards the diffusion node, the integration time of the respective photodiode can be defined.

According to an embodiment, the pixel arrangement further comprises a reset switch configured to reset the diffusion node between the transfers of the low sensitivity signal and the high sensitivity signal. The reset switch may further be configured to reset the diffusion node before transferring signals to the diffusion node. The reset gate may be implemented as reset switch. For example, the reset gate may be part of a reset transistor comprising a first terminal connected to a pixel supply voltage and a second terminal connected to the FD node. By applying a reset signal to the reset gate the reset transistor becomes conductive, such that any redundant charge carriers are removed by applying the pixel supply voltage. In this way, different video signals can be transferred to the diffusion node without interfering.

In an embodiment, the pixel arrangement further comprises an amplifying stage. The amplifying stage is electrically connected between the diffusion node and the sample-and-hold stage. The amplifying stage is configured to amplify the charge signals from the photosensitive stage. In particular, an input terminal of the amplifying stage is electrically connected to the diffusion node. The amplifying stage is configured to generate, based on the respective charge signal, an amplified signal. The charge signal may be one of the low sensitivity signal and the high sensitivity signal in charge domain, respectively. The amplified signal is a voltage signal that is based on the low sensitivity signal or the high sensitivity signal, respectively. The amplifying stage may form a common-drain amplifier, also known as source follower. A gate terminal of the source follower is connected to the FD node and serves as input terminal of the amplifying stage. A common terminal may be connected to the supply voltage. The respective amplified signal is generated at an output terminal of the amplifying stage. The amplifying stage may be used as voltage buffer and configured to buffer the signal, thus to decouple the FD node from further pixel components. The amplifying stage may further be configured to amplify the light-induced charge signal and reset levels.

In an embodiment, the sample-and-hold stage comprises a first pair of capacitors. The first pair of capacitors may by electrically connected to the amplifying stage via a first switch. The capacitors of the first pair of capacitors may be arranged cascaded. Thus, the two capacitors of the first pair of capacitors may be coupled to each other via a second switch. The first pair of capacitors may form a first branch of the S/H stage.

One capacitor of the first pair of capacitors is configured to store a reset level. That capacitor can be referred to as first capacitor. Another capacitor of the first pair of capacitors is configured to store the high sensitivity signal. That capacitor can be referred to as second capacitor. This can mean that the second capacitor stores an amplified version of the high sensitivity signal in the voltage domain. The reset level refers to a non-video signal of the pixel arrangement. By resetting the diffusion node, additional noise is introduced that is not correlated with the noise of the high or the low sensitivity signal. However, the reset level of the pixel arrangement comprises information about KTC noise, a kind of temporal deviation. Thus, advantageously, temporal noise of the pixel arrangement can be determined. A fixed pattern noise (FPN) of the pixel arrangement can be reduced and minimized by storing the reset level of the pixel on the first capacitor.

In an embodiment, the diffusion node is configured to store the low sensitivity signal. This can mean that the diffusion node stores the low sensitivity signal in a charge domain. By storing the low sensitivity signal on the diffusion node the pixel size can be reduced, since no additional storage capacitors are needed. Further, the reset and thermal noise is less relevant in this case and has not to be stored, since at high illuminance photon shot noise is dominant. However, this can possibly increase the SNR drop between the low sensitivity signal and the high sensitivity signal due to a kTC noise increase and higher dark signal non-uniformity (DSNU).

In an embodiment, the sample-and-hold stage further comprises a second pair of capacitors. The second pair of capacitors may by electrically connected to the amplifying stage via a third switch. The capacitors of the second pair of capacitors may be arranged cascaded. Thus, the two capacitors of the second pair of capacitors may be coupled to each other via a fourth switch. The second pair of capacitors may form a second branch of the S/H stage.

One capacitor of the second pair of capacitors is configured to store a further reset level. That capacitor can be referred to as third capacitor. Another capacitor of the second pair of capacitors is configured to store the low sensitivity signal. That capacitor can be referred to as fourth capacitor. This can mean that the fourth capacitor stores an amplified version of the low sensitivity signal in the voltage domain. The further reset level refers to a non-video signal of the pixel arrangement. The further reset level of the pixel arrangement comprises information about KTC noise. Thus, temporal noise of the pixel arrangement can be determined. A fixed pattern noise (FPN) of the pixel arrangement can be reduced and minimized by storing the further reset level of the pixel on the third capacitor. The reset level may originate from a reset of the diffusion node before the charge transfers from the photodiodes to the diffusion node, and the further reset level may originate from a reset of the diffusion node between the charge transfers, or vice-versa.

By storing the low sensitivity signal and the further reset level on the third and fourth capacitor, a SNR drop between the low sensitivity signal and the high sensitivity signal is advantageously reduced. The low sensitivity signal can be stored in the voltage domain. The kTC noise and the DSNU is taken into account. The low sensitivity signal, the high sensitivity signal, the reset level and the further reset level are stored until pixel readout. After pixel readout, the diffusion node, the first capacitor and the second capacitor, the third capacitor and the fourth capacitor may be configured to be reset.

In an embodiment, the first pair of capacitors and/or the second pair of capacitors are electrically connected to a readout stage of the pixel arrangement. In an embodiment, the first pair of capacitors and/or the second pair of capacitors are electrically connected to the readout stage via a further amplifying stage comprised by the pixel arrangement. The further amplifying stage may form a further common-drain amplifier, i.e. a further source follower, and may comprise a second further common-drain amplifier, i.e. a second further source follower. The further amplifying stage may be configured to generate pixel output signals at output terminals of the further amplifying stage. The further amplifying stage may be used as voltage buffer. The further amplifying stage may be configured to buffer the pixel output signals, thus to decouple the respective capacitors from the readout circuitry. The pixel output signals may be altered versions of the video signals and non-video signals stored on the pixel internal memory elements. In particular, the pixel output signals may be amplified versions of the video and non-video signals. A gate terminal of the (second) further source follower is electrically connected to the first (second) pair of capacitors. A common terminal of the (second) further source follower is connected to the pixel supply voltage. A pixel output signal is applied at an output terminal of the (second) further source follower.

In an embodiment, the pixel arrangement further comprises a dual conversion gain stage. The dual conversion gain stage comprises a further capacitor electrically coupled to the diffusion node via a gain switch. The further capacitor is configured to increase a capacitance of the diffusion node. The gain switch is arranged between the reset gate and the diffusion node. The gain switch can be implemented as transistor. The gain switch is provided for shorting the diffusion node and the further capacitor. The further capacitor may be implemented as MOS or MIM capacitor. Alternatively, the further capacitor may be implemented as metal fringe capacitor or as poly-N capacitor. A terminal node of the further capacitor is arranged between the reset gate and the gain switch. A further terminal node of the further capacitor may be grounded.

By shorting the FD node and the further capacitor a combined capacitance is larger than that of the FD node. Keeping the charge constant, this leads to a reduced voltage signal. Thus, the gain is reduced by enlarging the capacitance. This means that the pixel arrangement has a reduced gain if the FD node and the further capacitor are shorted. In other words, the pixel arrangement has an increased gain if the further capacitor is electrically decoupled from the FD node by the gain switch. Thus, a dynamic range of the pixel arrangement can further be increased by applying different gains to the low sensitivity signal and/or the high sensitivity signal.

In an embodiment, the pixel arrangement further comprises an overflow capacitor. The overflow capacitor is electrically coupled to the first photodiode of the first sub-pixel. The overflow capacitor is configured to store excess charge carriers from the first photodiode. The overflow capacitor may be electrically coupled to the first photodiode via the first transfer gate. A further transfer gate may be implemented between the diffusion node and the first transfer gate, so that charge carriers from the overflow capacitor may be transferred to the diffusion node via the further transfer gate.

If the first transfer gate is deactivated, the first photodiode is separated from the overflow capacitor by a potential barrier. This means that charge carriers are prevented from diffusing between the first photodiode and the overflow capacitor. In some embodiments, however, such charge overflow is allowed, especially if the potential well of the first photodiode is saturated. In this way, no photo-induced charge carriers are lost even during saturation, providing the pixel arrangement with an increased dynamic range. In other words, the overflow capacitor stores excess charge carriers. The excess charge carriers on the overflow capacitor and the charge signal from the first photodiode may be transferred separately to the diffusion node, so that the corresponding pixel output signals can be stored and read out separately.

In an embodiment, the pixel arrangement comprises one first sub-pixel and three second sub-pixels. The one first sub-pixel and the three second sub-pixels are arranged in a 2×2 array. This means that the pixel arrangement comprises four sub-pixels. This further means that the first sub-pixel occupies one quadrant of the 2×2 array. In a top view, the sub-pixels may have a rectangular, in particular square, shape. Alternatively, the three second sub-pixels are fused to form one photodiode with an enlarged L-shaped photoactive area. Fused sub-pixels may share one transfer gate. The three second sub-pixels or the one L-shaped second sub-pixel, respectively, partially surround the first sub-pixel in lateral directions. The photosensitive surfaces of all sub-pixels are arranged parallel and adjacent to each other facing the same direction, i.e. a direction that is perpendicular to a main plane of extension of the pixel arrangement. The first sub-pixel is surrounded in places by the second sub-pixel(s). Advantageously, the second sub-pixels cover a larger photoactive area than the first sub-pixel. Thus, a larger amount of charge carriers can be accumulated even at low light conditions. In view of the first sub-pixel, a reduced amount of charge carriers is accumulated, even at high light conditions.

Furthermore, a pixel matrix is provided. All features disclosed for the pixel arrangement are also disclosed for and applicable to the pixel matrix and vice-versa.

The pixel matrix comprises four pixel arrangements, wherein each pixel arrangement comprises one first sub-pixel and three second sub-pixels arranged in a 2×2 array as described above. The second sub-pixels may also be fused.

The pixel matrix may comprise a plurality of pixel arrangements, in particular more than four pixel arrangements, wherein the pixel arrangements are arranged in an M×N matrix with M and N being natural numbers. In this case, 2×2 sub-regions of the M×N matrix are arranged according to a configuration as described in the following. This means that the 2×2 matrix as described in the following may form a unit cell of the pixel matrix.

Four pixel arrangements, each of which comprising one first sub-pixel and three second sub-pixels arranged in a 2×2 array, are arranged in a 2×2 matrix, wherein the first sub-pixels of the pixel arrangements are arranged adjacent to each other in the center of the 2×2 matrix. The second sub-pixels of the respective pixel arrangements surround the first sub-pixels in lateral directions. Alternatively, at least some of the second sub-pixels are fused as described above. Additionally or alternatively, at least some of the first sub-pixels in the center of the matrix are fused. Such configuration may be preferred for manufacturing purposes. For example, the filter layer as described above can cover a continuous region above (or below) the four first sub-pixel in the center of the 2×2 pixel matrix.

In an alternative embodiment, four pixel arrangements, each of which comprising one first sub-pixel and three second sub-pixels arranged in a 2×2 array, are arranged in a 2×2 matrix in a same orientation, such that, in lateral directions, the first sub-pixels of the pixel arrangements are separated from each other by a respective second sub-pixel. For example, each first sub-pixel is arranged in a same corner of the 2×2 array. This arrangement can be advantageous to achieve a balanced spatial distribution of the sub-pixels. Adjacent second sub-pixels may be fused.

Furthermore, an image sensor is provided that comprises the pixel arrangement or the pixel matrix as described in one of the above embodiments. This means that all features disclosed for the pixel arrangement are also disclosed for and applicable to the image sensor and vice-versa.

The image sensor can be conveniently employed in optoelectronic devices, such as smart phones, tablet computers, laptops, or camera modules. Other applications include augmented reality (AR) and/or virtual reality (VR) scenarios. Further, the image sensor can be implemented in drones or scanning systems, as well as in industrial applications like machine vision. Further, the image sensor is in particular suited to be operated in global shutter mode, as the signals are stored in a pixel level memory. The global shutter mode is in particular suited for infrared applications, where the image sensor device further comprises a light source that is synchronized with the pixels. Thus, an optoelectronic device comprising such image sensor may also work in the infrared (IR) domain, for example for 3D imaging and/or identification purposes. Image sensors with infrared sensitivity can be used in dark environments where video feed is required. Such applications reach from mobile phone face unlock to driver monitoring systems. Both can deploy illuminators that are in the short-wave infrared (SWIR) or near-infrared (NIR) spectrum, so that the phone user/driver is not blinded by the light that is illuminating him/her.

Furthermore, a method for operating a pixel arrangement is provided. The pixel arrangement described above can preferably be employed for the method for operating the pixel arrangement described herein. This means that all features disclosed for the pixel arrangement, the pixel matrix and the image sensor are also disclosed for the method for operating the pixel arrangement and vice-versa.

The method for operating a pixel arrangement comprises generating, by a photosensitive stage comprising at least one sub-pixel of a first type and at least one sub-pixel of a second type, electrical signals by converting electromagnetic radiation. A low sensitivity signal is generated by a photodiode of the sub-pixel of the first type. A high sensitivity signal is generated by a photodiode of the sub-pixel of the second type. The method further comprises sampling and storing, by a sample-and-hold stage being coupled to the photosensitive stage via a diffusion node, the electrical signals from the photosensitive stage.

By means of the high sensitivity signal and the low sensitivity signal the pixel arrangement enables HDR operation. The HDR allows for better highlight and shadow capturing encountered in real world scenes.

In an embodiment, the method further comprises transferring, by a first transfer gate, the low sensitivity signal of the first sub-pixel (sub-pixel of the first type) to the diffusion node. Transferring the low sensitivity signal may be triggered by applying a first transfer signal to the first transfer gate. In an embodiment, the method further comprises transferring, by a second transfer gate, the high sensitivity signal of the second sub-pixel (sub-pixel of the second type) to the diffusion node. Transferring the high sensitivity signal may be triggered by applying a second transfer signal to the second transfer gate. In an embodiment, the method further comprises resetting, by a reset switch, the diffusion node between the transfers of the low sensitivity signal and the high sensitivity signal. Resetting can be triggered by applying a reset signal to the reset switch. By triggering the transfer to the diffusion node, the integration time of the respective photodiodes can be defined. By resetting the diffusion node redundant charge carriers are removed. In this way, different video and non-video signals can be transferred to the diffusion node without interfering.

In an embodiment, the method further comprises sampling and storing a reset level on a capacitor of a first pair of capacitors of the sample-and-hold-stage. Sampling may be performed by activating a first and/or a second switch of the S/H stage, so that the capacitor is electrically connected. The reset level may be stored on the capacitor by releasing the second switch.

The method may further comprise sampling and storing the high sensitivity signal on another capacitor of the first pair of capacitors. Sampling may be performed by activating a first switch of the S/H stage, so that the capacitor is electrically connected. The high sensitivity signal may be stored on the capacitor by releasing the first switch. An altered version of the high sensitivity charge signal from the second photodiode may be stored. The high sensitivity signal is stored in the voltage domain and may be amplified by an interposed amplifying stage between the S/H stage and the diffusion node, as described above.

In an embodiment, the method further comprises sampling and storing a further reset level on a capacitor of a second pair of capacitors of the sample-and-hold-stage. Sampling may be performed by activating a third and/or a fourth switch of the S/H stage, so that the capacitor is electrically connected. The reset level may be stored on the capacitor by releasing the fourth switch. The reset level may originate from a reset of the diffusion node before the charge transfers from the photodiodes to the diffusion node, while the further reset level may originate from a reset of the diffusion node between the charge transfers, or vice-versa.

In an embodiment, the method comprises sampling and storing the low sensitivity signal on another capacitor of the second pair of capacitors. Sampling may be performed by activating the third switch of the S/H stage, so that the capacitor is electrically connected. The low sensitivity signal may be stored on the capacitor by releasing the third switch. An altered version of the low sensitivity charge signal from the second photodiode may be stored. The low sensitivity signal is stored in the voltage domain and may be amplified by the interposed amplifying stage between the S/H stage and the diffusion node.

In an embodiment, the method further comprises reading out, by a readout stage, the reset level, the further reset level, the low sensitivity signal and the high sensitivity signal. This can mean that the pixel output signals are forwarded to a readout circuit. The readout circuit is not comprised by the pixel arrangement. The readout stage may comprise a select gate that is activated by applying a select signal. The select gate may be activated in combination with one or more switches (first to fourth switch) of the S/H stage, so that the signal on the respective capacitor is read out.

By storing the low sensitivity signal, the high sensitivity signal and the reset levels on the respective capacitors, a SNR drop between the low sensitivity signal and the high sensitivity signal is advantageously reduced. The signals can be stored in the voltage domain. The kTC noise and the DSNU is taken into account. Further, correlated double sampling (CDS) can be performed.

In an embodiment, the method further comprises storing the low sensitivity signal on the diffusion node. The low sensitivity signal is stored on the diffusion node by transferring the charge signal from the first photodiode to the diffusion node via the first transfer gate. The low sensitivity signal is stored as a charge signal in the charge domain. Advantageously, a pixel size can be reduced as no further capacitors are required. Thermal noise and the further reset level might be neglected, since in the low sensitivity signal shot noise is dominant.

Further embodiments of the method become apparent to the skilled reader from the embodiments of the pixel arrangement described above, and vice-versa.

### BRIEF DESCRIPTION OF THE DRAWINGS

The following description of figures may further illustrate and explain aspects of the pixel arrangement and the method of operating such pixel arrangement. Components and parts of the pixel arrangement that are functionally identical or have an identical effect are denoted by identical reference symbols. Identical or effectively identical components and parts might be described only with respect to the figures where they occur first. Their description is not necessarily repeated in successive figures.

FIG. 1A shows an exemplary embodiment of a pixel arrangement.

FIG. 1B shows an exemplary signal timing for the pixel arrangement according to FIG. 1A.

FIG. 2 shows another exemplary embodiment of a pixel arrangement.

FIG. 3 shows another exemplary embodiment of a pixel arrangement.

FIG. 4 shows another exemplary embodiment of a pixel arrangement.

FIG. 5 shows an exemplary embodiment of a pixel matrix comprising a pixel arrangement.

FIG. 6 shows another exemplary embodiment of a pixel matrix comprising a pixel arrangement.

FIG. 7 shows a schematic of a semiconductor device comprising a pixel arrangement.

FIG. 8 shows a schematic of an image sensor comprising a pixel arrangement or a pixel matrix.

### DETAILED DESCRIPTION

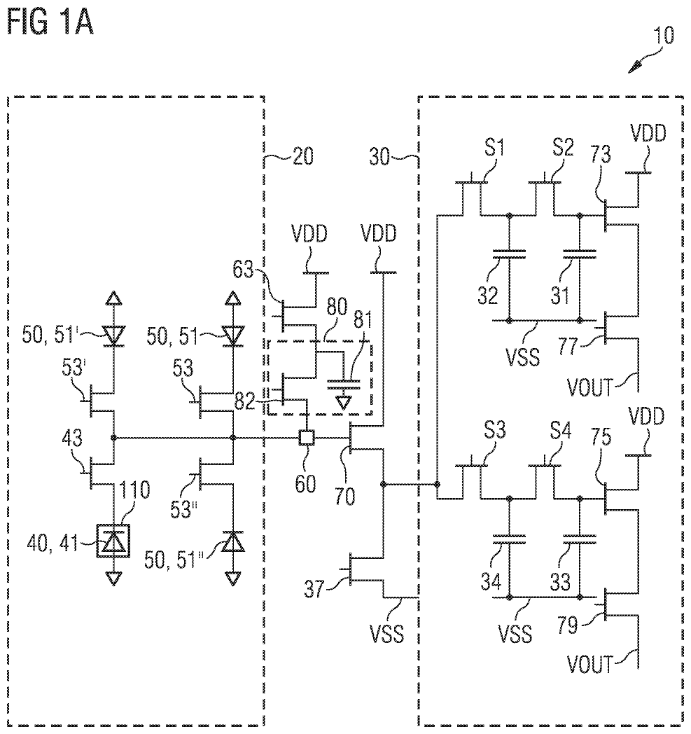

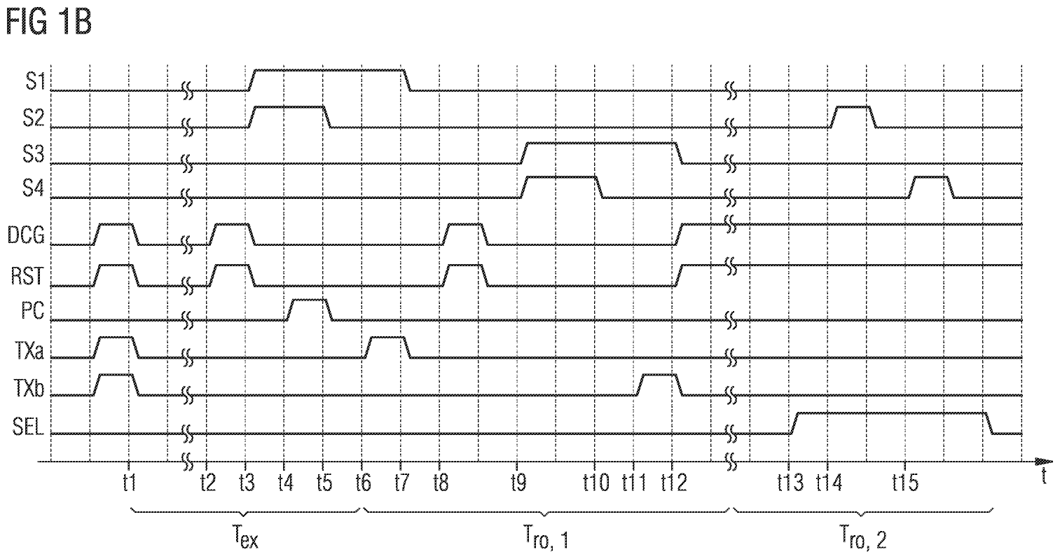

In FIG. 1A an exemplary embodiment of a pixel arrangement 10 is shown. The shown pixel arrangement 10 can be operated to achieve a high dynamic range (HDR). The pixel arrangement 10 comprises a photosensitive stage 20 being configured to generate electrical signals by converting electromagnetic radiation. The photosensitive stage 20 forms at least one sub-pixel of a first type 40 (in the following referred to as first sub-pixel 40) comprising a photodiode 41 (in the following referred to as first photodiode 41) that is configured generate a low sensitivity signal. Further, the photosensitive stage 20 forms at least one sub-pixel of a second type 50 (in the following referred to as second sub-pixel 50) comprising a photodiode 51 (in the following referred to as second photodiode 51) that is configured to generate a high sensitivity signal. The pixel arrangement 10 further comprises a sample-and-hold stage 30, wherein the sample-and-hold 30 stage is electrically coupled to the photosensitive stage 20 via a diffusion node 60 and configured to sample and store the electrical signals from the photosensitive stage 20.

The shown embodiment comprises one first sub-pixel 40 with a first photodiode 41 and three second sub-pixels 50 with a respective second photodiode 51, 51′ and 51″. For the sake of readability, the three second photodiodes 51, 51′ and 51″ are grouped together only with the reference sign 51. The photodiodes 41, 51 each comprise an anode terminal and a cathode terminal. An anode terminals of the photodiodes 41, 51 are connected to a negative pixel supply voltage VSS, which can also be ground (GND). The photodiodes 41, 51 may convert light of any wavelength region, for example visible light, infrared light and/or ultraviolet light. The first photodiode 41 and the second photodiodes 51 may be configured to detect electromagnetic radiation in a substantially same or at least overlapping wavelength range, in particular the infrared wavelength range. The first photodiode may be provided with a filter layer 110, as indicated. The filter layer 110 is configured to reduce an intensity of the electromagnetic radiation. Additionally or alternatively, an integration time of the first photodiode 41 is shorter than an integration time of the second photodiode(s) 51.

The pixel arrangement 10 further comprises a first transfer gate 43 between the first photodiode 41 and a diffusion node 60 of the pixel arrangement 10. Further, the pixel arrangement 10 comprises a second transfer gate 53, 53′ and 53″ between each of the second photodiodes 51, 51′,51″ and the diffusion node 60. The first transfer gate 43 is configured to transfer the low sensitivity signal of the first sub-pixel 40 to the diffusion node 60, while the second transfer gate 53 (53′,53″) is configured to transfer the high sensitivity signal of the second sub-pixel(s) to the diffusion node 60.

In the shown example, the transfer gates 43, 53 are implemented as part of a respective transfer transistor, which acts as a switch. A first terminal of the transfer transistor is electrically connected to the cathode terminal of the photodiode 41 or 51, respectively. A second terminal of the transfer transistor is electrically connected to the diffusion node 60, also called FD node 60 in the following. The FD node 60 may be implemented as capacitor. The transfer gates 43, 53 are configured to receive a respective transfer signal TX, TX′ for transferring the respective charge signal from the photodiodes 41, 51 to the FD node 60.

In the shown example, the pixel arrangement 10 further comprises a reset switch 63 electrically coupled to the FD node 60 for resetting the FD node 60. This can mean that the reset switch 63 is configured to reset the diffusion node 60 between the transfers of the low sensitivity signal and the high sensitivity signal. In the embodiment shown in FIG. 1A the reset switch 63 is implemented as a reset transistor. A first terminal of the reset transistor is electrically connected to a pixel supply voltage VDD. A second terminal of the reset transistor is electrically connected to the FD node 60 (via an optional gain switch 82). The gate (reset gate) of the reset transistor is configured to receive a reset signal RST for resetting the FD node 60 by applying the pixel supply voltage VDD and therefore removing any redundant charge carrier.

In the shown example, the pixel arrangement 10 further comprises an optional dual conversion gain stage 80. The dual conversion gain stage 80 comprises a gain switch 82 between the FD node 60 and the reset switch 63. Thus, in this embodiment, the reset switch 63 is electrically coupled to the FD node 60 via the gain switch 82. The gain switch may be implemented as transistor comprising a first terminal connected to the FD node 60 and a second terminal connected to the reset switch 63. Further, the dual conversion gain stage 80 comprises a further capacitor 81. The further capacitor 81 comprises a terminal node electrically connected to the second terminal of the gain switch and a further terminal node connected to VSS, as indicated. By applying a gain signal to the gain switch (gate of transistor) the transistor becomes conductive, such that the FD node 60 is shorted with the further transistor 81. Thus, a combined capacitance can be increased and a conversion gain can be reduced.

In the shown example, the pixel arrangement 10 further comprises an amplifying stage 70, which is electrically connected between the FD node 60 and the sample-and-hold stage 30. The amplifying stage 70 is configured to amplify the electrical signals from the photosensitive stage 20. The amplifying stage 70 may form, as shown in FIG. 1A, a common-drain amplifier, also known as source follower. A gate terminal of the source follower is connected to the FD node 60 and serves as input terminal of the amplifying stage 70. A common terminal is connected to the supply voltage VDD. The respective amplified signal is generated at an output terminal of the source follower.

The sample-and-hold-stage 30, S/H stage 30, of the pixel arrangement 10 shown in FIG. 1 further comprises a first pair of capacitors 31, 32 and a second pair of capacitors 33, 34.

The first pair of capacitors 31, 32 is electrically connected to the amplifying stage 70 via a first switch S1. The capacitors of the first pair of capacitors 31, 32 are arranged cascaded. The two capacitors of the first pair of capacitors 31, 32 are coupled to each other via a second switch S2. The first pair of capacitors forms a first branch of the S/H stage. The second pair of capacitors 33, 34 is electrically connected to the amplifying stage 70 via a third switch S3. The capacitors of the second pair of capacitors 33, 34 are arranged cascaded. The two capacitors of the second pair of capacitors 33, 34 are coupled to each other via a fourth switch S4. The second pair of capacitors 33, 34 forms a second branch of the S/H stage 30, which is arranged parallel to the first branch of the S/H stage 30. The switches S1 to S4 may be formed by transistors comprising a respective gate for receiving a switch signal.

One capacitor 31 (also referred to as first capacitor 31) of the first pair of capacitors 31, 32 is configured to store a reset level before readout. Another capacitor 32 (also referred to as second capacitor 32) of the first pair of capacitors 31, 32 is configured to store the high sensitivity signal before readout. One capacitor 33 (also referred to as third capacitor 33) of the second pair of capacitors 33, 34 is configured to store a further reset level before readout. Another capacitor 34 (also referred to as fourth capacitor 34) of the second pair of capacitors 33, 34 is configured to store the low sensitivity signal before readout.

Each of the capacitors 31 to 34 comprises a respective terminal node that is connected to VSS, as shown in FIG. 1A. The first switch S1 is arranged between the output terminal of the amplifying stage 70 and a further terminal node of the second capacitor 32. The first switch S1 is provided for transferring the respective amplified signal to the first and the second capacitor 31, 32. The second switch S2 is arranged between the further terminal node of the second capacitor 32 and a further terminal node of the first capacitor 31. The second switch S2 is provided for transferring the respective amplified signal to the first capacitor 31. The third switch S3 is arranged between the output terminal of the amplifying stage 70 and a further terminal node of the fourth capacitor 34. The third switch S3 is provided for transferring the respective amplified signal to the third and the fourth capacitor 33, 34. The fourth switch S4 is arranged between the further terminal node of the fourth capacitor 34 and a further terminal node of the third capacitor 33. The fourth switch S4 is provided for transferring the respective amplified signal to the third capacitor 33.

The pixel arrangement 10 according to FIG. 1A further comprises a further amplifying stage. The further amplifying stage is formed by a further source follower 73 and a second further source follower 75. A gate terminal of the further source follower 73 is electrically connected to the first branch of the S/H stage 30, in particular to the further terminal node of the first capacitor 31. A gate terminal of the second further source follower 75 is electrically connected to the second branch of the S/H stage 30, in particular to the further terminal node of the third capacitor 33. Common terminals of the further source follower 73 and the second further source follower 75 are connected to VDD. The further source follower 73 and the second further source follower 75 are configured to generate pixel output signals at respective output terminals.

The pixel arrangement 10 according to FIG. 1A further comprises a readout stage. The readout stage is formed by a first select gate 77 and a second select gate 79.

The select gates 77, 79 may form part of a respective transistor. The first select gate 77 is arranged between the output terminal of the further source follower 73 and a column bus and is provided for transferring the pixel output signals VOUT stored in the first branch of the S/H stage 30 to the column bus. The second select gate 79 is arranged between the output terminal of the second further source follower 75 and the column bus and is provided for transferring the pixel output signals VOUT stored in the second branch of the S/H stage 30 to the column bus. By applying a select signal SEL, SEL′ to the select gates 77, 79 the pixel output signals VOUT are forwarded to a readout circuit (not shown).

The pixel arrangement 10 according to FIG. 1A further comprises a precharge switch 37 electrically coupled to the output terminal of the amplifying stage 70. The precharge switch 37 may be provided for precharging the capacitors 31 to 34, which can in particular mean that the capacitors 31 to 34 are discharged before new signals are stored. As shown in FIG. 1A, the precharge switch 37 may form part of a transistor comprising a first terminal connected to the output terminal of the amplifying stage 70 and a second terminal connected to VSS. By applying a precharge signal PC to the precharge switch 37 the capacitors can be discharged.

In FIG. 1B operating the pixel arrangement 10 according to FIG. 1A is illustrated in more detail and with respect to signal timing. However, it should be noted that the signal timing shown is more of an example and could be varied. Furthermore, the scaling of the time intervals should not be taken as an exact indication.

It can be seen that operating the pixel arrangement 10 can be divided into several time intervals, wherein the first time interval Tₑₓ is provided for pixel exposure. A second time interval Tᵣₒ is provided for frame storage and pixel readout or row readout, respectively. The second time interval Tᵣₒ is subdivided into two stages. The first stage T_{ro,1} consists of the charge carrier transfer from the photodiode(s) to the S/H stage. The second stage T_{ro,2} consists of signal readout on the column/row from the S/H stage. In this context, row readout can mean readout of a single row. Rows can be read out sequentially, wherein all rows require the same time interval T_{ro,2}. As the pixel arrangement 10 can be a global shutter pixel, the pixel exposure and frame storage can be a global operation, i.e. pixel exposure and frame storage can affect each pixel in a matrix of pixels simultaneously. However, reading out pixels can be a local operation, since the pixels or rows of a pixel matrix can be read one after the other.

FIG. 1B shows the timing of a first transfer signal TXa for controlling the first transfer gate 43, and of a second transfer signal TXb for controlling the second transfer gate(s) 53, 53′,53″. Further, it shows the timing of a reset signal RST, of a precharge signal PC, of a select signal SEL and of a gain signal DCG for controlling the reset switch 63, the precharge switch 37, the select gate 77, 79 and the gain switch 82, respectively. Moreover, the timing of the signals controlling the first to fourth switch S1-S4 is shown (the respective signals are denoted by S1-S4 as well). All signals can be in an activated state (high state) or in a deactivated state (low state). Applying or activating the respective signal can mean that the signal is switched to the activated state. Deactivating the respective signal can mean that the signal is switched to the deactivated state. In the following, the timing is explained in more detail using selected points in time t1-t15 shown in the figure.

At the beginning of the exposure time Tₑₓ at time t1 the gain signal DCG, the reset signal RST and the transfer signals TXa, TXb are switched from an activated state into a deactivated state. The respective signals have formed a pulse which may be called shutter pulse or reset pulse. Thus, the trailing edge of the shutter pulse indicates the beginning of the sequence, in particular the beginning of the exposure time Tₑₓ.

At time t2 the gain signal DCG and the reset signal RST are pulsed, which means that the diffusion node 60 is ready to accumulate charge carriers after it has been reset. At time t3 the first switch signal S1 and the second switch signal S2 are activated, so that the first and the second capacitors 31, 32 are electrically connected to the diffusion node 60 and electrical signals can be stored thereon.

At time t4 the precharge signal is pulsed, so that the capacitors 31 to 34 of the S/H stage are discharged before new signals are stored thereon. At time t5 the second switch signal S2 is deactivated. In turn, a reset level of the pixel arrangement 10 is stored on the first capacitor 31.

The exposure time interval Tₑₓ ends at time t6. Here, the first transfer signal TXa is applied, such that the respective charge signal is transferred from the first photodiode 41 to the diffusion node 60. This results in the low sensitivity signal that is transferred to the second capacitor 32 as the first switch signals S1 is still in the activated state.

At time t7 the first transfer signal TXa and the first switch signal S1 are both deactivated, so that the low sensitivity signal (or an altered version thereof) is stored on the second capacitor 32. At time t8 the gain signal DCG and the reset signal RST are activated for resetting the diffusion node 60. Thus, the diffusion node 60 is ready for another signal to be stored thereon.

At time t9 the third switch signal S3 and the fourth switch signal S4 are activated, so that the third and the fourth capacitors 33, 34 are electrically connected to the diffusion node 60 and electrical signals can be stored thereon. At time t10 the fourth switch signal S4 is deactivated. In turn, a further reset level of the pixel arrangement 10 is stored on the third capacitor 33.

The second transfer signal TXb is applied at time t11, such that the respective charge signal is transferred from the second photodiode(s) 51, 51′,51″ to the diffusion node 60. In particular, t11 is later in time than t6. This can mean that the integration time of the second photodiode(s) 51, 51′,51″ is greater than the integration time of the first photodiode 41.

The electrical signal from the second photodiode(s) 51, 51′,51″ is transferred as high sensitivity signal to the fourth capacitor 34, since the third switch signals S3 is still in the activated state. At time t12 the second transfer signal TXb and the third switch signal S3 are both deactivated, so that the high sensitivity signal (or an altered version thereof) is stored on the fourth capacitor 34. At the same time the reset signal RST and the gain signal DCG are activated resetting the diffusion node 60 and indicating that the frame storage T_{ro,2} is finished. Further, this prevents imaging issues such as blooming. The reset signal RST is activated after the high sensitivity signal is stored.

Pixel readout starts by applying the select signal SEL at time t13. At this instant of time the reset level stored on the first capacitor 31 and the further reset level stored on the third capacitor 33 can be read out. The low sensitivity signal stored on the second capacitor 32 is read out at time t14 by applying the second switch signal S2. Starting with time t15 the high sensitivity signal is read out by activating the fourth switch signal S4. After that, the pixel arrangement 10 is ready for the next frame.

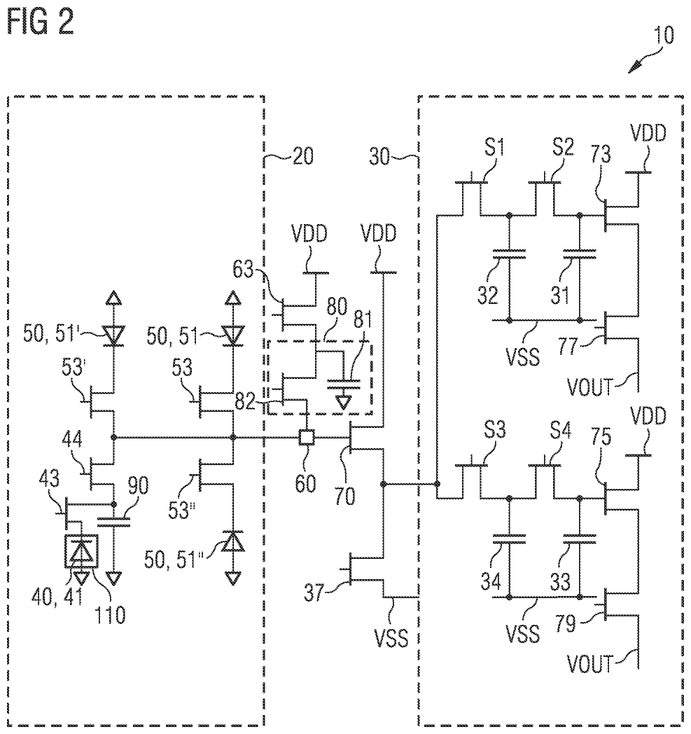

In FIG. 2 another embodiment of the pixel arrangement 10 is shown. The embodiment according to FIG. 2 is different from the embodiment according to FIG. 1 in that it comprises an optional overflow capacitor 90. The overflow capacitor 90 is electrically coupled to the first photodiode 41 of the first sub-pixel 40 and configured to store excess charge carriers from the first photodiode 41. A first terminal node of the overflow capacitor 90 is electrically connected to VSS. A further terminal node of the overflow capacitor 90 is electrically connected to the first photodiode 41 via the transfer gate 43 and to the diffusion node 60 via a further transfer gate 44.

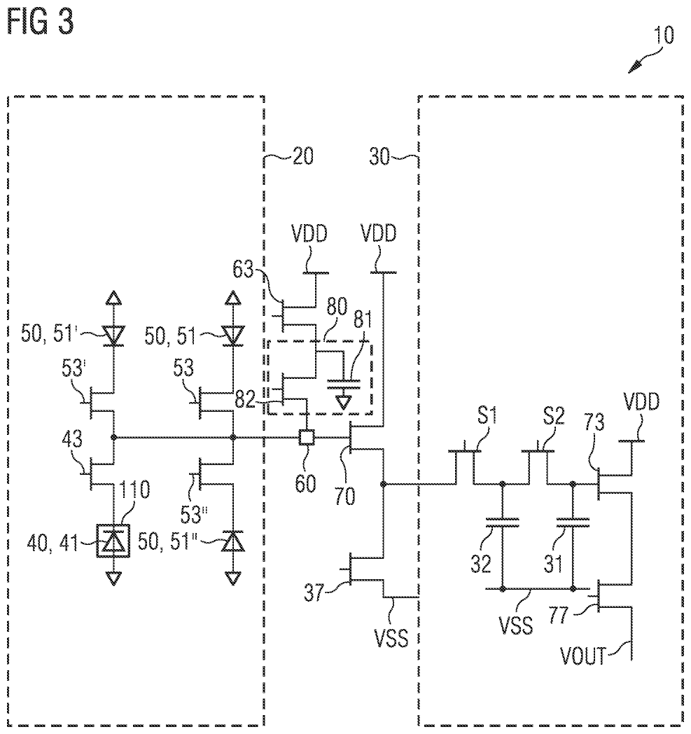

In FIG. 3 another embodiment of the pixel arrangement 10 is shown. The embodiment according to FIG. 3 is different from the embodiment according to FIG. 1 in that the S/H stage 30 comprises only one branch (the first branch). In that embodiment, the low sensitivity signal is to be stored on the diffusion node 60 before readout.

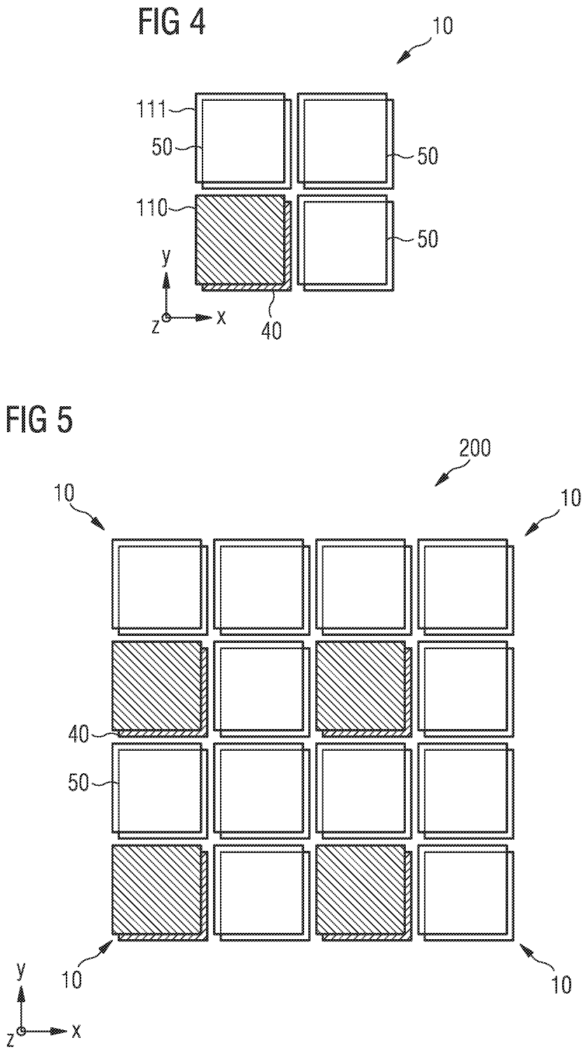

In FIG. 4 an exemplary embodiment of the pixel arrangement 10 is shown in a top-view. The pixel arrangement 10 may represent one pixel within a matrix of pixels and is subdivided in at least two sub-pixels, i.e. the sub-pixel of the first type 40 and the sub-pixel of the second type 50. In the shown embodiment, the pixel arrangement 10 comprises one sub-pixel of the first type 40 (first sub-pixel 40) and three sub-pixels of the second type 50 (second sub-pixels 50) that are arranged in a 2×2 array. For example and as indicated, the first subpixel 40 may be covered by a filter layer 110 which is a semitransparent film. The second sub-pixels 50 may be covered by a clear film 111, for example. The S/H stage 30 may be arranged in the periphery of the pixel arrangement 10 or between the sub-pixels 40, 50 and is not shown in FIG. 4. The photosensitive surfaces of all sub-pixels 40, 50 are arranged parallel and adjacent to each other facing the same direction z, i.e. a direction that is perpendicular to a main plane of extension that runs in lateral directions x, y. The first sub-pixel 40 is arranged in one corner/quadrant of the 2×2 array. The second sub-pixels 50 may also be fused to form one L-shaped sub-pixel 50.

In FIG. 5 a pixel matrix 200 is shown that comprises a plurality of pixel arrangements 10 according to FIG. 4. The embodiment of FIG. 5 comprises four pixel arrangements 10 according to FIG. 4. However, the shown pixel matrix 200 may represent a unit cell of a larger pixel matrix 200 comprising more than four pixel arrangements 10. The photosensitive surfaces of all pixel arrangements 10 are arranged parallel and adjacent to each other facing the same direction z, i.e. a direction that is perpendicular to a main plane of extension that runs in lateral directions x, y. The pixel arrangements 10 are arranged in a 2×2 matrix and in a same orientation, such that, in lateral directions x, y, the first sub-pixels 40 of the respective pixel arrangements 10 are separated from each other by one second sub-pixel 50. This means that the first sub-pixels 40 are arranged in a same corner/quadrant of the 2×2 array forming the respective pixel arrangements 10. Adjacent sub-pixels of the same type may be fused.

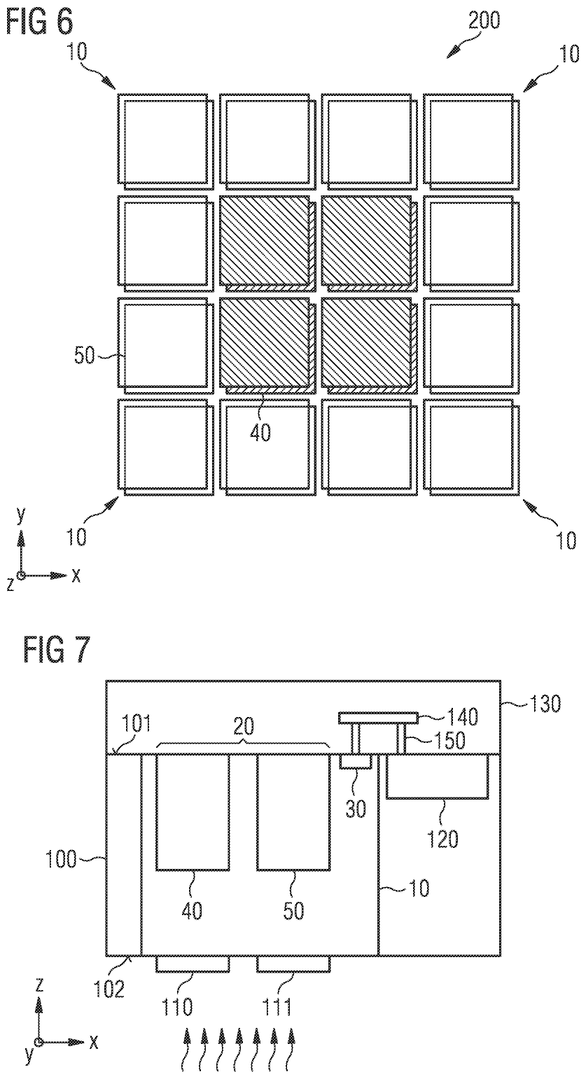

In FIG. 6 an alternative configuration of a pixel matrix 200 is shown. Again, the shown pixel matrix 200 may represent a unit cell of a larger pixel matrix 200 comprising more than four pixel arrangements 10. The pixel arrangements 10 are arranged in a 2×2 matrix, wherein the sub-pixels of the first type 40 of the respective pixel arrangements 10 are arranged adjacent to each other in the center of the 2×2 matrix, and wherein the sub-pixels of the second type 50 of the respective pixel arrangements 10 surround the sub-pixels of the first type 40 in lateral directions x, y. This means that the individual pixel arrangements are aligned differently. Adjacent sub-pixels of the same type may be fused.

FIG. 7 shows a schematic cross-section of a semiconductor device comprising the pixel arrangement 10. The photosensitive stage 20 and the sample-and-hold stage 30 of the pixel arrangement 10 are arranged on a main surface 101 of a semiconductor substrate 100. The semiconductor substrate 100 comprises a back surface 102 that is, in the transversal direction z, opposite the main surface 101. The photosensitive stage 20 is illuminated by electromagnetic radiation from the back surface 102 of the semiconductor substrate 100, as indicated by arrows. Thus, the pixel arrangement may be backside illuminated (BSI).

A filter layer 110 that may be arranged on or at the back surface 102 of the substrate 100 is aligned with the first sub-pixel 40. A clear film 111 that may also be arranged on the back surface 102 of the substrate 100 is aligned with the second sub-pixel 50. The filter layer 110 is provided to attenuate the intensity of the electromagnetic radiation before it reaches the photodiode of the first sub-pixel 40. Thus, the filter layer 110 is arranged between the first sub-pixel 40 and the incident electromagnetic radiation.

Moreover, a readout circuit 120 may be arranged on the main surface 101 of the substrate 100. The readout circuit 120 may be electrically connected to the pixel arrangement 10 by a wiring. It is further shown in FIG. 7 that a dielectric layer 130 may be arranged on the main surface 101 of the substrate 100. Metal layers 140 and contact plugs 150 may be embedded in the dielectric layer 130 and form the wiring.

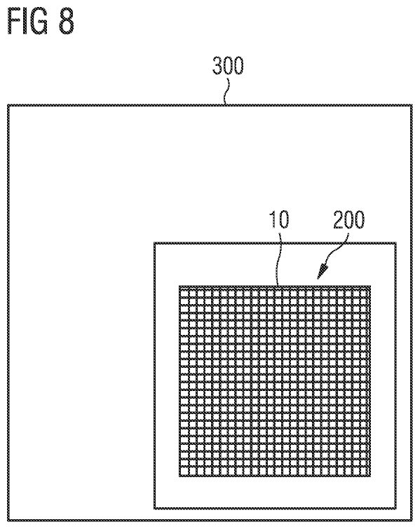

In FIG. 8 an image sensor 300 comprising the pixel arrangement 10 is shown schematically. The pixel arrangements 10 of the image sensor 300 can be arranged in a two-dimensional pixel matrix 200, as indicated in FIG. 8. The image 300 may comprise further components (not shown), for example other circuit elements or a light source that is synchronized with the pixels 10.

The embodiments of the pixel arrangement 10 and the method of operating such pixel arrangement 10 disclosed herein have been discussed for the purpose of familiarizing the reader with novel aspects of the idea. Although preferred embodiments have been shown and described, many changes, modifications, equivalents and substitutions of the disclosed concepts may be made by one having skill in the art without unnecessarily departing from the scope of the claims.

It will be appreciated that the disclosure is not limited to the disclosed embodiments and to what has been particularly shown and described hereinabove. Rather, features recited in separate dependent claims or in the description may advantageously be combined. Furthermore, the scope of the disclosure includes those variations and modifications, which will be apparent to those skilled in the art and fall within the scope of the appended claims.

The term “comprising”, insofar it was used in the claims or in the description, does not exclude other elements or steps of a corresponding feature or procedure. In case that the terms “a” or “an” were used in conjunction with features, they do not exclude a plurality of such features. Moreover, any reference signs in the claims should not be construed as limiting the scope.

Reference Symbols
10 pixel arrangement
20 photosensitive stage
30 sample-and-hold stage
31-34 capacitors
37 precharge switch
40 sub-pixel of first type
41 photodiode
43 first transfer gate
50 sub-pixel of second type
51 photodiode
53 second transfer gate
60 diffusion node
63 reset switch
70 amplifying stage, source follower
73 further source follower
75 second further source follower
77 first select gate
79 second select gate
80 dual conversion gain stage
81 further capacitor
82 gain switch
90 overflow capacitor
100 semiconductor substrate
101 main surface of substrate
102 back surface of substrate
110 filter layer
111 clear film
120 readout circuit
130 dielectric layer
140 metal layer
150 contact plugs
200 pixel matrix
300 image sensor
DCG gain signal
PC precharge signal
RST reset signal
S1-S4 first to fourth switch, switch signal
SEL select signal
t1-t15 point in time
Tₑₓ exposure time
T_{ro,1} T_{ro,2} readout time
TX,TXa,TXb transfer signal
VOUT pixel output signal
VSS negative pixel supply voltage, GND
VDD pixel supply voltage
x,y lateral directions
z transversal direction

1. A pixel arrangement comprising:
a photosensitive stage configured to generate electrical signals by converting electromagnetic radiation, wherein the photosensitive stage forms at least one sub-pixel of a first type comprising a photodiode that is configured to generate a low sensitivity signal, and at least one sub-pixel of a second type comprising a photodiode that is configured to generate a high sensitivity signal, and
a sample-and-hold stage, wherein the sample-and-hold stage is electrically coupled to the photosensitive stage via a diffusion node and configured to sample and store the electrical signals from the photosensitive stage.

2. The pixel arrangement according to claim 1, wherein the photodiode of the sub-pixel of the first type and the photodiode of the sub-pixel of the second type are configured to detect electromagnetic radiation in a substantially same or at least overlapping wavelength range, in particular the infrared wavelength range.

3. The pixel arrangement according to claim 1, wherein the photosensitive stage and the sample-and-hold stage are arranged at or on a main surface of a semiconductor substrate, and wherein the photosensitive stage is illuminated by electromagnetic radiation from a back surface of the semiconductor substrate.

4. The pixel arrangement according to claim 1, further comprising a filter layer between the incident electromagnetic radiation and the sub-pixel of the first type, wherein the filter layer is configured to reduce an intensity of the electromagnetic radiation.

5. The pixel arrangement according to claim 1, wherein an integration time of the photodiode of the sub-pixel of the first type is shorter than an integration time of the photodiode of the sub-pixel of the second type.

6. The pixel arrangement according to claim 1, further comprising:
a first transfer gate configured to transfer the low sensitivity signal of the sub-pixel of the first type to the diffusion node,
a second transfer gate configured to transfer the high sensitivity signal of the sub-pixel of the second type to the diffusion node, and
a reset switch configured to reset the diffusion node between the transfers of the low sensitivity signal and the high sensitivity signal.

7. The pixel arrangement according to claim 1, further comprising an amplifying stage electrically connected between the diffusion node and the sample-and-hold stage and being configured to amplify the electrical signals from the photosensitive stage.

8. The pixel arrangement according to claim 1, wherein the sample-and-hold stage comprises a first pair of capacitors, wherein one capacitor of the first pair of capacitors is configured to store a reset level before readout, and wherein another capacitor of the first pair of capacitors is configured to store the high sensitivity signal before readout, and wherein the diffusion node (60) is configured to store the low sensitivity signal before readout.

9. The pixel arrangement according to claim 1, wherein the sample-and-hold stage further comprises a first pair of capacitors and a second pair of capacitors, wherein one capacitor of the first pair of capacitors is configured to store a reset level before readout, and wherein another capacitor of the first pair of capacitors is configured to store the high sensitivity signal before readout, and wherein one capacitor of the second pair of capacitors is configured to store a further reset level before readout, and wherein another capacitor of the second pair of capacitors is configured to store the low sensitivity signal before readout.

10. The pixel arrangement according to claim 1, further comprising a dual conversion gain stage comprising a further capacitor electrically coupled to the diffusion node via a gain switch and configured to increase a capacitance of the diffusion node.

11. The pixel arrangement according to claim 1, further comprising an overflow capacitor electrically coupled to the photodiode of the sub-pixel of the first type and configured to store excess charge carriers from said photodiode.

12. The pixel arrangement according to claim 1, wherein one sub-pixel of the first type and three sub-pixels of the second type are arranged in a 2×2 array.

13. A pixel matrix comprising four pixel arrangements according to claim 12, wherein the pixel arrangements are arranged in a 2×2 matrix, wherein the sub-pixels of the first type are arranged adjacent to each other in the center of the 2×2 matrix, and wherein the sub-pixels of the second type surround the sub-pixels of the first type in lateral directions.

14. A pixel matrix comprising four pixel arrangements according to claim 12, wherein the pixel arrangements are arranged in a 2×2 matrix in a same orientation, such that, in lateral directions, the sub-pixels of the first type are separated from each other by a respective sub-pixel of the second type.

15. An image sensor comprising the pixel arrangement according to one of claim 1.

16. A method for operating a pixel arrangement, the method comprising:
generating, by a photosensitive stage comprising at least one sub-pixel of a first type and at least one sub-pixel of a second type, electrical signals by converting electromagnetic radiation, wherein a low sensitivity signal is generated by a photodiode of the sub-pixel of the first type, and wherein a high sensitivity signal is generated by a photodiode of the sub-pixel of the second type,
sampling and storing, by a sample-and-hold stage being coupled to the photosensitive stage via a diffusion node, the electrical signals from the photosensitive stage.

17. The method according to claim 16, the method further comprising:
transferring, by a first transfer gate, the low sensitivity signal of the sub-pixel of the first type to the diffusion node,
transferring, by a second transfer gate, the high sensitivity signal of the sub-pixel of the second type to the diffusion node, and
resetting, by a reset switch, the diffusion node between the transfers of the low sensitivity signal and the high sensitivity signal.

18. The method according to claim 16, further comprising:
sampling and storing a reset level on a capacitor of a first pair of capacitors of the sample-and-hold-stage,
sampling and storing the high sensitivity signal on another capacitor of the first pair of capacitors,
sampling and storing a further reset level on a capacitor of a second pair of capacitors of the sample-and-hold-stage,
sampling and storing the low sensitivity signal on another capacitor of the second pair of capacitors,
reading out, by a readout stage, the reset level, the further reset level, the low sensitivity signal and the high sensitivity signal.

19. The method according to claim 16, further comprising:
sampling and storing a reset level on a capacitor of a first pair of capacitors of the sample-and-hold-stage,
sampling and storing the high sensitivity signal on another capacitor of the first pair of capacitors,
storing the low sensitivity signal on the diffusion node,
reading out, by a readout stage, the reset level, the low sensitivity signal and the high sensitivity signal.
